(19) United States
(12) Patent Application Publication
(10) Pub. No.: US 2017/0200884 A1
(43) Pub. Date: Jul. 13, 2017

(54) CONFIGURATIONS AND TECHNIQUES TO INCREASE INTERFACIAL ANISOTROPY OF MAGNETIC TUNNEL JUNCTIONS

(71) Applicant: Intel Corporation, Santa Clara, CA (US)

(72) Inventors: Kaan OGUZ, Hillsboro, OR (US); Mark L. DOCZY, Portland, OR (US); Brian S. DOYLE, Portland, OR (US); Charles C. KUO, Hillsboro, OR (US); Anurag CHAUDHRY, Portland, OR (US); Robert S. CHAU, Beaverton, OR (US)

(21) Appl. No.: 15/324,589

(22) PCT Filed: Aug. 5, 2014
(86) PCT No.: PCT/US2014/049794

§ 371 Date: Jan. 6, 2017

(51) Int. Cl. H01L 43/08; H01L 27/22; H01L 43/12; G11C 11/16; H01L 43/10

(52) U.S. Cl. CPC H01L 43/08; G11C 11/161; H01L 43/10; H01L 43/12; H01L 27/228

(57) ABSTRACT

Embodiments of the present disclosure describe configurations and techniques to increase interfacial anisotropy of magnetic tunnel junctions. In embodiments, a magnetic tunnel junction may include a cap layer, a tunnel barrier, and a magnetic layer disposed between the cap layer and the tunnel barrier. A buffer layer may, in some embodiments, be disposed between the magnetic layer and a selected one of the cap layer or the tunnel barrier. In such embodiments, the interfacial anisotropy of the buffer layer and the selected one of the cap layer or the tunnel barrier may be greater than an interfacial anisotropy of the magnetic layer and the selected one of the cap layer or the tunnel barrier. Other embodiments may be described and/or claimed.

### FIELD

Embodiments of the present disclosure generally relate to the field of integrated circuits, and more particularly, to configurations and techniques to increase interfacial anisotropy of magnetic tunnel junctions.

### BACKGROUND

Some magnetic memories, such as a spin transfer torque memory (STTM), utilize a magnetic tunnel junction (MTJ) for switching and detection of the memory's magnetic state. Thermal stability of these memories is a concern; however, current techniques to increase thermal stability in the MTJ may increase resistance in the MTJ.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings. Unless explicitly indicated otherwise, the figures are not depicted in scale.

FIG. 1 schematically illustrates a cross-section side view of an integrated circuit (IC) assembly, in accordance with various embodiments of the present disclosure.

FIGS. 2-6 schematically illustrate different MTJ stack configurations having a buffer layer in accordance with various embodiments of the present disclosure.

FIG. 7 is a graphical depiction of interfacial anisotropic constants (Ki) associated with interfaces between various materials.

FIG. 8 illustrates a flow diagram for a method of fabricating an MTJ in accordance with various embodiments of the present disclosure.

FIG. 9 schematically illustrates an example system that may include memory cells having an MTJ configured in accordance with various embodiments of the present disclosure.

### DETAILED DESCRIPTION

A magnetic tunnel junction may be formed from two ferromagnetic layers separated by an insulating layer, also known as a tunnel barrier. One of the two ferromagnetic layers may be a strong magnet with a fixed polarity, also known as a fixed magnetic layer. The other ferromagnetic layer may be configured to undergo a change in polarity when a spin-polarized current is applied to it, and is also known as a free magnetic layer.

The change in polarity of the free magnetic layer may act to increase or decrease the electrical resistance across the MTJ. If the polarity of the free magnetic layer is the same as (e.g., parallel to) the polarity of the fixed magnetic layer, then the MTJ may be in a low resistance state. On the other hand, if the polarity of the free magnetic layer is opposite (e.g., anti-parallel to) the polarity of the fixed magnetic layer, then the MTJ may be in a high resistance state. In such magnetic memories, the magnetic state is what may cause data to persist in the memory, and the data may be read by measuring the resistance across the MTJ. As a result, stability of the free magnetic layer to maintain polarity, absent application of a spin-polarized current, is essential for maintaining the state of the MTJ.

Regarding STTM specifically, one form of STTM includes perpendicular STTM (pSTTM). Where a traditional MTJ or non-perpendicular MTJ generates a magnetization “in plane” (with which “high” and “low” memory states are set), a perpendicular MTJ (pMTJ) generates magnetization “out of plane.” This reduces the switching current needed to switch between the high resistance state and the low resistance state. This also allows for better scaling (e.g., smaller size memory cells). Traditional MTJs are converted to pMTJs by, for example, thinning the free layer in the presence of interface magnetic anisotropy, thereby making the tunnel barrier/free layer interface more dominant in magnetic field influence (the interface promotes anisotropic out of plane magnetization).

Embodiments of the present disclosure describe configurations and techniques to increase interfacial anisotropy of magnetic tunnel junctions. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group), and/or memory (shared, dedicated, or group) that execute one or more software or firmware programs, a combinational logic circuit, and/or other suitable components that provide the described functionality.

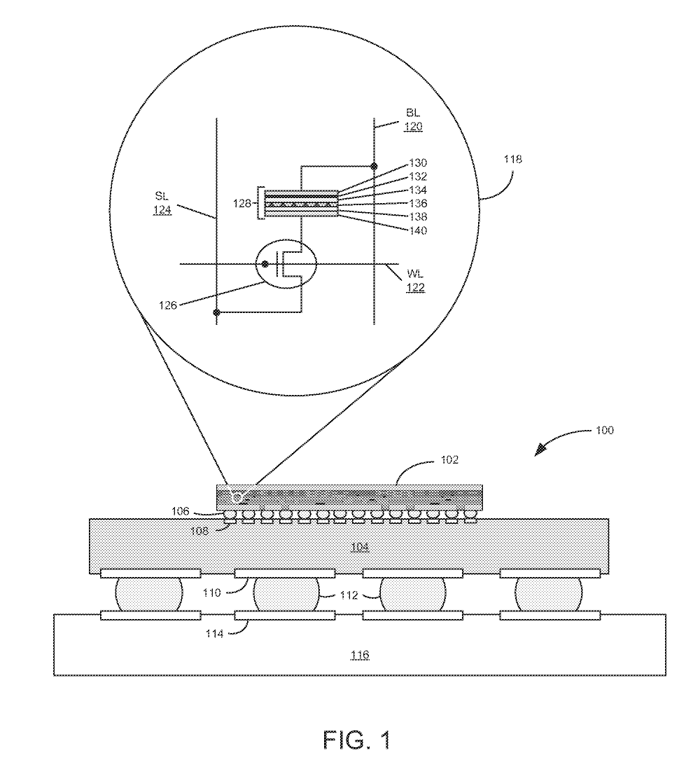

FIG. 1 schematically illustrates a cross-section side view of an example integrated circuit (IC) assembly 100, in accordance with various embodiments of the present disclosure. In some embodiments, the IC assembly 100 may include one or more dies (e.g., IC die 102) electrically and/or physically coupled with a package substrate 104, as can be seen. The package substrate 104 may further be electrically coupled with a circuit board 116, as can be seen.

Die 102 may be attached to package substrate 104 according to a variety of suitable configurations, including a flip-chip configuration, as depicted, or other configurations, such as, for example, being embedded in the package substrate 104 or being configured in a wirebonding arrangement. In the flip-chip configuration, the die 102 may be attached to a surface of the package substrate 104 via die interconnect structures 106 such as bumps, pillars, or other suitable structures that may also electrically couple die 102 with the package substrate 104.

Die 102 may include embedded memory cells (e.g., spin transfer torque random access memory (STT-RAM) 118). STT-RAM 118 may include a magnetic tunnel junction (MTJ) 128. In some embodiments, MTJ 128 may include a first cap layer 130, a buffer layer 132, ferromagnetic layers 134 and 138, a tunnel barrier 136 separating ferromagnetic layers 134 and 138, and a second cap layer 140. In embodiments, buffer layer 132 may be selected to increase thermal stability, hereinafter referred to merely as “stability,” of MTJ 128 by increasing the interfacial anisotropy of MTJ 128 when compared with embodiments without buffer layer 132. Interfacial anisotropy is a directional energy created from the interface, or contact area, between two materials. Interfacial anisotropy may be measured by the amount of energy created per area of interface (e.g., millijoules per square meter (mJ/m²)). The interfacial anisotropy between two materials varies based on the materials selected. Interfacial anisotropy is the energy responsible for converting an in-plane MTJ to an out-of-plane MTJ, or perpendicular MTJ (pMTJ). In addition, interfacial anisotropy is cumulative, so the interfacial anisotropy of an MTJ would be the sum of the individual interfacial anisotropies for each interface of the MTJ. A greater overall interfacial anisotropy of the MTJ corresponds with greater stability of polarity in the free magnetic layer.

The MTJ may couple bit line (BL) 120 to selection switch 126 (e.g., transistor), word line (WL) 122, and sense line (SL) 124. STT-RAM 118 may be read by assessing a change of resistance (e.g., tunneling magnetoresistance (TMR)) for different relative magnetizations of ferromagnetic layers 134 and 138. More specifically, MTJ resistance may be determined by the relative polarization of layers 134 and 138. When the polarization of layers 134 and 138 are opposite, or anti-parallel, the MTJ may be in a high resistance state. When the polarization of layers 134 and 138 are the same, or parallel, the MTJ may be in a low resistance state. In embodiments, layer 138 may be a fixed magnetic layer because its polarization may be fixed. As a result, ferromagnetic layer 134 may be a free magnetic layer. As discussed above, a free magnetic layer is a magnetic layer that may be configured to undergo a change in polarity by applying a driving current polarized by the fixed layer (e.g., a positive voltage applied to layer 138 rotates the magnetization direction of layer 134 opposite to that of layer 138 and negative voltage applied to layer 138 rotates the magnetization direction of layer 134 to the same direction of layer 138).

STT-RAM 118, described above, is just one example of a “beyond CMOS” technology (or “non-CMOS based” technology), which relates to devices and processes not entirely implemented with complementary metal-oxide-semiconductor (CMOS) techniques. Beyond CMOS technology may rely on spin polarization (which concerns the degree to which the spin or intrinsic angular momentum of elementary particles is aligned with a given direction) and, more generally, spintronics (a branch of electronics concerning the intrinsic spin of an electron, its associated magnetic moment, and the electron's fundamental electronic charge). Spintronics devices may concern TMR, which uses quantum-mechanical tunneling of electrons through a thin insulator to separate ferromagnetic layers, and STT, where a current of spin-polarized electrons may be used to control the magnetization direction of ferromagnetic electrodes.

Beyond CMOS devices include, for example, spintronics devices implemented in memory (e.g., 3 terminal STT-RAM), spin logic devices (e.g., logic gates), tunnel field-effect transistors (TFETs), impact ionization MOS (IMOS) devices, nano-electro-mechanical switches (NEMS), negative common gate FETs, resonant tunneling diodes (RTD), single electron transistors (SET), spin FETs, nanomagnet logic (NML), domain wall logic, domain wall memory, and the like.

Die 102 may represent a discrete chip made from a semiconductor material and may be, include, or be a part of a processor, memory, or ASIC in some embodiments. In some embodiments, an electrically insulative material such as, for example, molding compound or underfill material (not pictured) may partially encapsulate a portion of die 102 and/or interconnect structures 106. Die interconnect structures 106 may be configured to route electrical signals between die 102 and package substrate 104.

Package substrate 104 may include electrical routing features configured to route electrical signals to or from die 102. The electrical routing features may include, for example, traces disposed on one or more surfaces of package substrate 104 and/or internal routing features such as, for example, trenches, vias, or other interconnect structures to route electrical signals through package substrate 104. For example, in some embodiments, package substrate 104 may include electrical routing features (such as die bond pads 108) configured to receive die interconnect structures 106 and route electrical signals between die 102 and package substrate 104.

In some embodiments, the package substrate 104 is an epoxy-based laminate substrate having a core and/or build-up layers such as, for example, an Ajinomoto Build-up Film (ABF) substrate. The package substrate 104 may include other suitable types of substrates in other embodiments including, for example, substrates formed from glass, ceramic, or semiconductor materials.

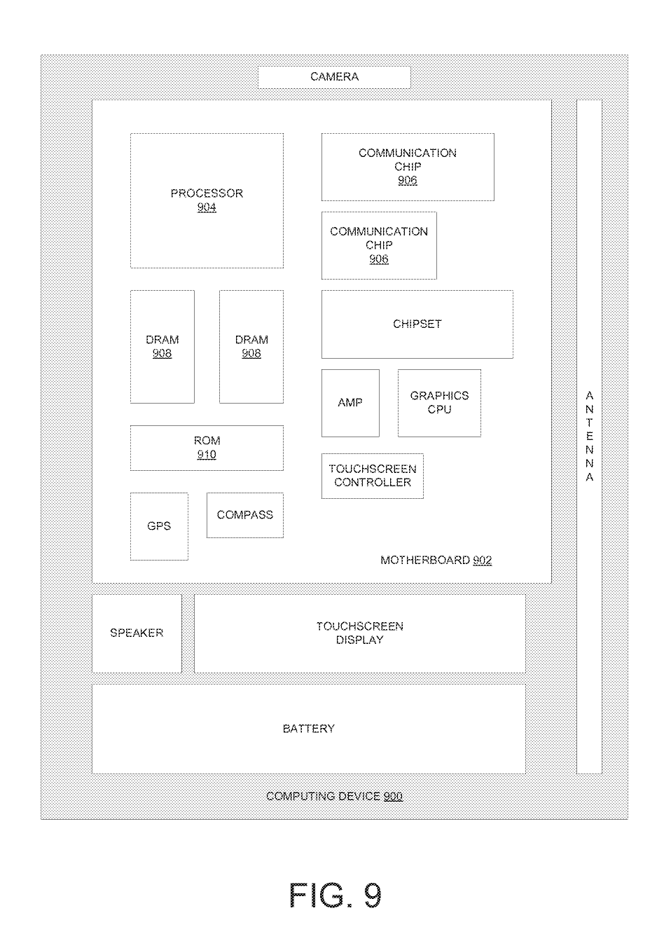

Circuit board 116 may be a printed circuit board (PCB) composed of an electrically insulative material such as an epoxy laminate. For example, circuit board 116 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Structures (not shown), for example, vias, may be formed through the electrically insulating layers to route the electrical signals of die 102 through circuit board 116. Circuit board 116 may be composed of other suitable materials in other embodiments. In some embodiments, circuit board 116 is a motherboard (e.g., motherboard 902 of FIG. 9).

Package-level interconnects such as, for example, solder balls 112 or land-grid array (LGA) structures may be coupled to one or more lands (hereinafter “lands 110”) on package substrate 104 and one or more pads 114 on circuit board 116 to form corresponding solder joints that are configured to further route the electrical signals between package substrate 104 and circuit board 116. Other suitable techniques to physically and/or electrically couple package substrate 104 with circuit board 116 may be used in other embodiments.

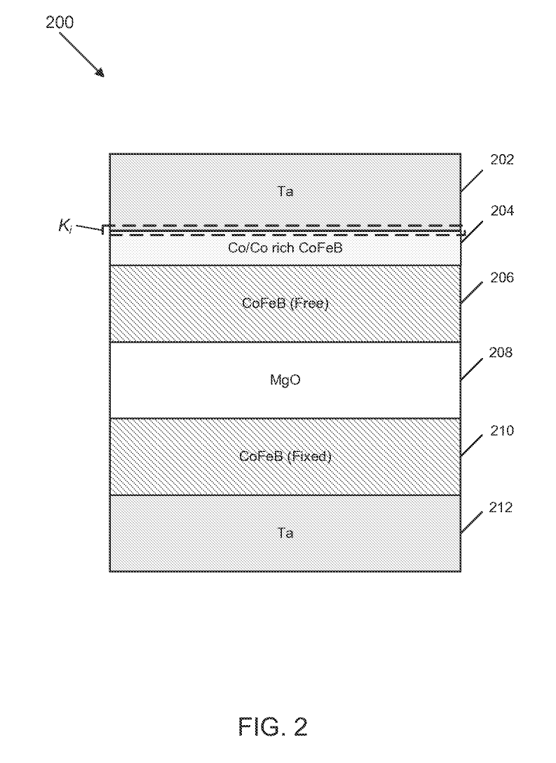

FIGS. 2-6 schematically illustrate different MTJ configurations having a buffer layer in accordance with various embodiments of the present disclosure. FIG. 2 schematically depicts MTJ 200, which is an embodiment of MTJ 128 of FIG. 1. As depicted, MTJ 200 may include a first cap layer 202, a buffer layer 204, ferromagnetic layers 206 and 210, a tunnel barrier 208 separating ferromagnetic layers 206 and 210, and a second cap layer 212.

First and second cap layers 202 and 212 may, in some embodiments, be composed of tantalum (Ta), as depicted. In other embodiments, first and second cap layers 202 and 212, respectively, may be composed of other material, such as, for example, hafnium (Hf), ruthenium (Ru), titanium (Ti), zirconium (Zr), molybdenum (Mo), tungsten (W), vanadium (V), chromium (Cr), niobium (Nb) and alloys of these materials. In embodiments, ferromagnetic layer 206 may be a free magnetic layer and ferromagnetic layer 210 may be a fixed magnetic layer, hereinafter referred to as free magnetic layer 206 and fixed magnetic layer 210, respectively. Free magnetic layer 206 and fixed magnetic layer 210 may be composed of a combination of cobalt (Co), iron (Fe), and boron (B). In some embodiments, CoFeB may be Fe rich, for example, the CoFeB may be composed of 20% Co, 60% Fe, and 20% B. In some embodiments, CoFeB may be Co rich, for example, the CoFeB may be composed of 60% Co, 20% Fe, and 20% B. As mentioned above, free magnetic layer 206 and fixed magnetic layer 210 may be separated by tunnel barrier 208. In some embodiments, tunnel barrier 208 may be composed of magnesium oxide (MgO), as depicted. In other embodiments, tunnel barrier 208 may be composed of other materials, such as, for example, hafnium oxide (HfO₂).

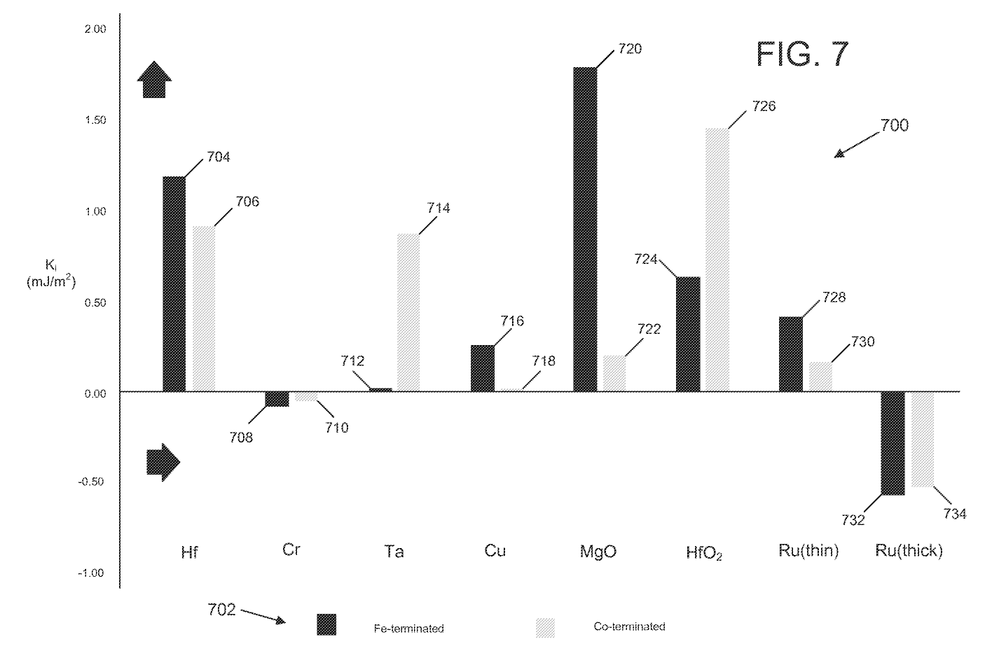

Buffer layer 204 may, in some embodiments, be disposed between first cap layer 202 and free magnetic layer 206. In embodiments, buffer layer 204 may be selected, or designed, such that an interface between buffer layer 204 and first cap layer 202 has a greater interfacial anisotropy, depicted as Kᵢ, than an interfacial anisotropy of the free magnetic layer 206 and first cap layer 202. For example, as depicted, buffer layer 204 may be composed of Co, which, as discussed further in reference to FIG. 7, below, has a greater interfacial anisotropy with Ta than the free magnetic layer 206 would have. As a result, the overall, or aggregate, interfacial anisotropy of MTJ 200 is increased through the addition of buffer layer 204. In further embodiments, buffer layer 204 may be another magnetic layer composed of Co rich CoFeB, such as that discussed above. Because Co rich CoFeB has a higher concentration of Co it would have a higher interfacial anisotropy with the Ta of cap layer 202 than an Fe rich CoFeB, such as that discussed above. In such an embodiment, free magnetic layer 206 may be Fe rich CoFeB, to increase the interfacial anisotropy with tunnel barrier 208, and free magnetic layer 206 and buffer layer 204 may be magnetically coupled. In other embodiments, buffer layer 204 may be disposed between free magnetic layer 206 and tunnel barrier 208. In such embodiments, buffer layer 204 may be selected, or designed, such that an interface between buffer layer 204 and tunnel barrier 208 has a greater interfacial anisotropy than an interfacial anisotropy of the free magnetic layer 206 and tunnel barrier 208. For example, referring to graph 700 of FIG. 7, a buffer layer of Fe or Co may be utilized where the tunnel barrier 208 is MgO; however, as depicted in graph 700, a buffer layer of Fe would have a much greater impact on the overall interfacial anisotropy of MTJ 200.

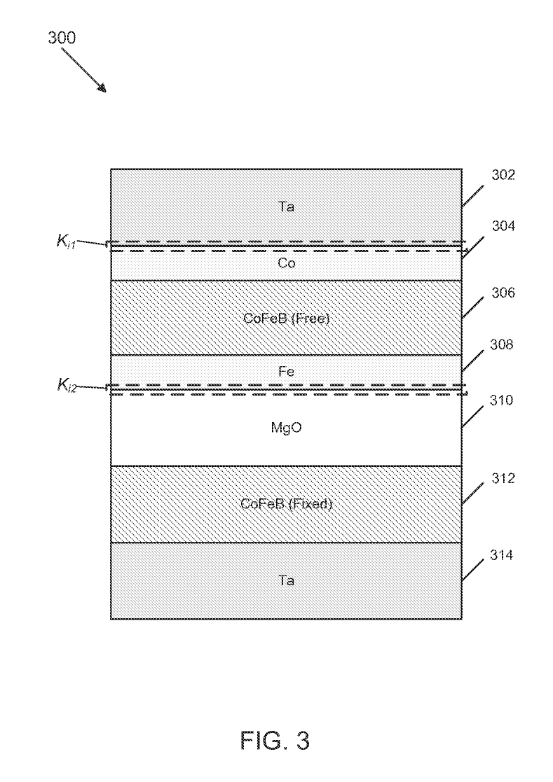

FIG. 3 schematically depicts MTJ 300. MTJ 300 depicts a configuration similar to MTJ 200 of FIG. 2. Like MTJ 200, MTJ 300 comprises first and second cap layers 302 and 314, respectively, free magnetic layer 306 and a fixed magnetic layer 312 separated by a tunnel barrier 310. MTJ 300 may also have a first buffer layer 304 disposed between first cap layer 302 and free magnetic layer 306 that may, as discussed above in reference to FIG. 2, have a greater interfacial anisotropy, depicted as Kᵢ₁, than an interfacial anisotropy of free magnetic layer 306 and first cap layer 302, respectively. Each of these components may be composed of the respective materials discussed above in reference to FIG. 2.

MTJ 300 differs from MTJ 200 of FIG. 2 in that MTJ 300 has a second buffer layer 308 disposed between free magnetic layer 306 and tunnel barrier 310. In embodiments, second buffer layer 308 may be selected, or designed, such that an interface between second buffer layer 308 and tunnel barrier 310 has a greater interfacial anisotropy, depicted as Kᵢ₂, than an interfacial anisotropy of free magnetic layer 306 and tunnel barrier 310. For example, as depicted, second buffer layer 308 may be composed of Fe, which, as discussed further in reference to FIG. 7, below, has a high interfacial anisotropy with MgO. As a result, the interfacial anisotropy of MTJ 300 is increased, not only through the addition of the first buffer layer 304, but also through the addition of the second buffer layer 308, so the overall interfacial anisotropy of MTJ 300 may be increased by the sum of Ki₁ and Ki₂.

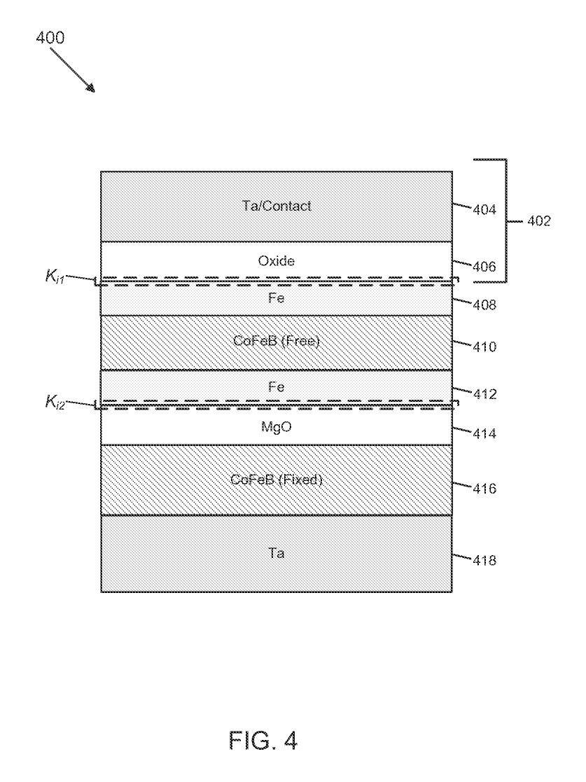

FIG. 4 schematically depicts MTJ 400. MTJ 400 may be composed of first cap layer 402, first buffer layer 408, free magnetic layer 410, second buffer layer 412, tunnel barrier 414, fixed magnetic layer 416, and second cap layer 418. Second cap layer 418 may be composed of Ta, as depicted, Hf, or any other suitable material. In embodiments, free magnetic layer 410 and fixed magnetic layer 416 may be composed of a combination of cobalt (Co), iron (Fe), and boron (B). As discussed above, in some embodiments, CoFeB may be Fe rich, for example, the CoFeB may be composed of 20% Co, 60% Fe, and 20% B, or any other suitable combination. Tunnel barrier 414 may be composed of MgO, as depicted, HfO₂, or any other suitable material.

In some embodiments, first cap layer 402 may be composed of a contact sub-layer 404 and an oxide sub-layer 406. In embodiments, oxide sub-layer 406 may be composed of MgO. In such an embodiment, first buffer layer 408 may be composed of Fe, as depicted, or Co; however, as can be seen from graph 700 of FIG. 7, the MgO/Fe interface would have a greater impact on interfacial anisotropy of MTJ 400. In other embodiments, oxide sub-layer 406 may be composed of HfO₂. In such an embodiment, first buffer layer 408 may be composed of Fe, as depicted, or Co; however, as can be seen from graph 700 of FIG. 7, the HfO₂/Co interface would have a greater impact on interfacial anisotropy of MTJ 400. In still other embodiments, oxide sub-layer 406 may be composed of a conductive oxide such as, for example, tungsten oxide (WO₂), vanadium oxide (VO and/or V₂O₂), indium oxide (InOₓ), aluminum oxide (Al₂O₃), ruthenium oxide (RuOₓ), and/or tantalum oxide (TaOₓ). In any of the above discussed embodiments, the overall interfacial anisotropy of MTJ 400 may be increased by the sum of Kᵢ₁ and Kᵢ₂. In embodiments utilizing an oxide sub-layer, such as oxide sub-layer 406, a resistance area (RA) product of the resulting MTJ may also be taken into consideration when selecting material for the oxide sub-layer.

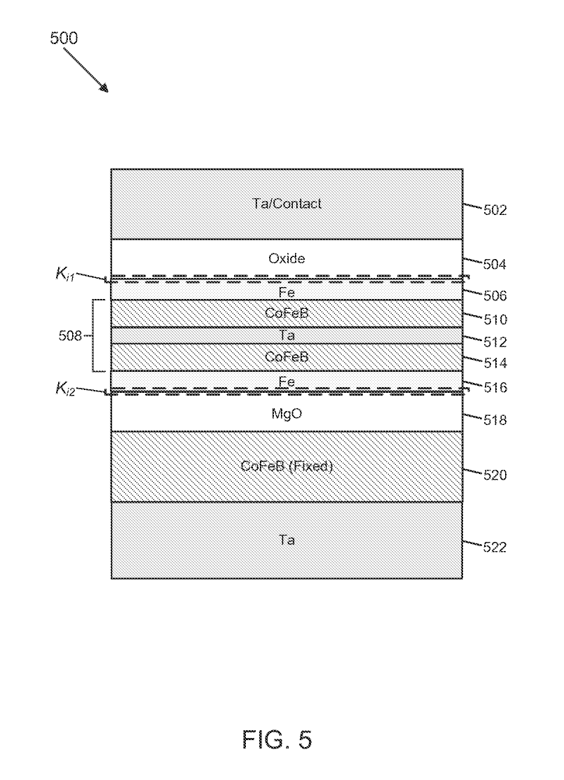

FIG. 5 schematically depicts MTJ 500. MTJ 500 depicts a configuration similar to MTJ 400 of FIG. 4. Like MTJ 400, MTJ 500 comprises a first cap layer having a contact sub-layer 502 and an oxide sub-layer 504, first buffer layer 506, second buffer layer 516, tunnel barrier 518, fixed magnetic layer 520, and second cap layer 522. Each of these components may be composed of the respective materials discussed above. MTJ 500 differs from MTJ 400 in that free magnetic layer 508 may be composed of a number of sub-layers 510-514 that may be magnetically coupled. As depicted, sub-layers 510-514 may include, but are not limited to, a first CoFeB layer 510, a Ta middle layer 512, and another CoFeB layer 514.

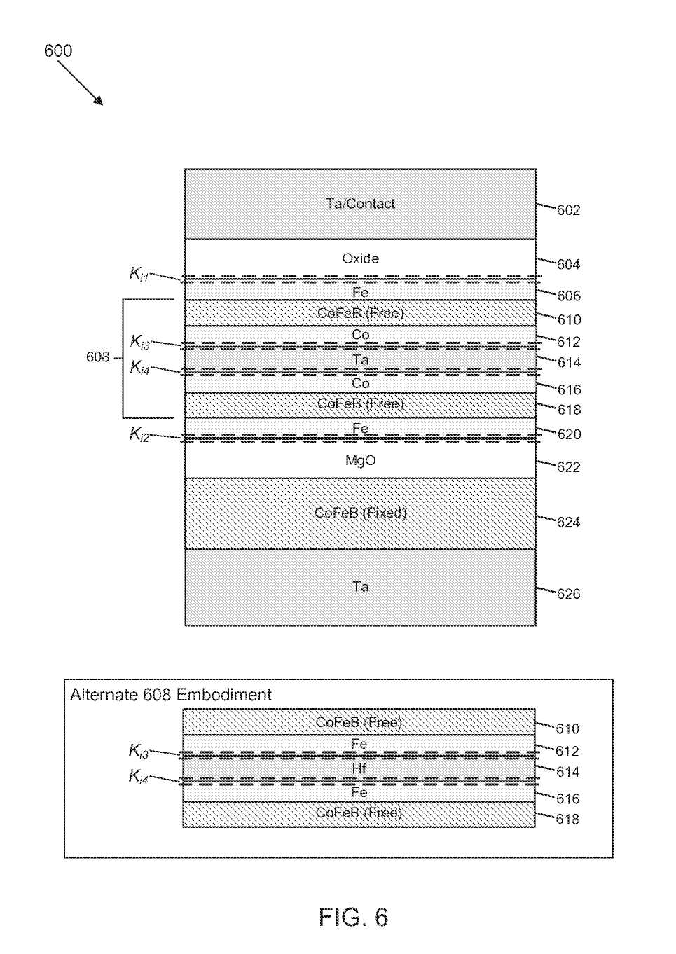

FIG. 6 schematically depicts MTJ 600. MTJ 600 depicts a configuration similar to MTJ 500 of FIG. 5. Like MTJ 500, MTJ 600 comprises a first cap layer having a contact sub-layer 602 and an oxide sub-layer 604, first buffer layer 606, second buffer layer 620, tunnel barrier 622, fixed magnetic layer 624, and second cap layer 626. Each of these components may be composed of the respective materials discussed above. MTJ 600 may also include a free magnetic layer 608 that may be composed of a number of sub-layers 610-618 that may be magnetically coupled.

MTJ 600 differs from MTJ 500 in that sub-layers 610-618 may include buffer sub-layers 612 and 616. Buffer sub-layers 612 and 616 may be selected, or designed, such that an interface between buffer sub-layer 612 or 616 and an adjacent sub-layer 614 has a greater interfacial anisotropy, depicted as Kᵢ₃ and Kᵢ₄, than an interfacial anisotropy of the MTJ without buffer sub-layers 612 and 616. As a result, the overall interfacial anisotropy of MTJ 600 may be increased by the sum of Kᵢ₁-Kᵢ₄. In some embodiments, only a single buffer sub-layer 612 or 616 may be utilized instead of both 612 and 616 being utilized. As depicted, in some embodiments, buffer sub-layers 612 and 616 may be composed of Co and adjacent sub-layer 614 may be composed of Ta. In an alternate embodiment, as depicted in the box labeled alternate 608 embodiment, buffer sub-layers 612 and 616 may be composed of Fe and adjacent sub-layer 614 may be composed of Hf. It will be appreciated that these are merely illustrative embodiments and that any other suitable material, or combination of materials, such as, for example, those materials discussed in reference to FIG. 7 may be utilized without departing from the scope of this disclosure. In other embodiments, free magnetic layer 608 may include any number of additional sub-layers and/or buffer sub-layers without departing from the scope of the present disclosure.

FIG. 7 is a graphical depiction of interfacial anisotropic constants (Ki) associated with interfaces between various materials. As discussed above, interfacial anisotropy is a directional energy created from the interface, or contact area, between two materials. The interfacial anisotropy between two materials varies based on the materials selected. Interfacial anisotropy is cumulative, so the interfacial anisotropy of an MTJ would be the sum of the individual interfacial anisotropies for each interface of the MTJ. The greater the overall interfacial anisotropy of the MTJ is, the more stable a polarity of a free magnetic layer is. A positive value of Kᵢ indicates that the polarity of the magnetization is in the perpendicular direction conversely, a negative value indicates that the polarity is in-plane. The X-axis depicts the various materials while the Y-axis depicts the corresponding Kᵢ in mJ/m² for the interface of the respective material with one of iron (Fe) or cobalt (Co), as indicated by legend 702. It will be appreciated that graph 700 depicts only a subset of possible materials and that materials not depicted should not be excluded from the scope of this disclosure merely based on the omission of the material from graph 700.

Starting from the left, the first material depicted is hafnium (Hf). As can be seen at bar 704 and bar 706, Hf has a positive Kᵢ when interfacing with Fe or Co. As a result, a buffer layer of either of Fe or Co may be utilized to interface with Hf; however, an interface of Hf and Fe clearly generates a greater Kᵢ, as depicted by bar 704.

The next material depicted is chromium (Cr). As can be seen at bar 708 and bar 710, Cr has a negative Kᵢ when interfacing with Fe or Co. As a result, a buffer layer of either Fe or Co may not be desirable to interface with Cr where the goal is to increase overall Kᵢ.

Moving to the right, the next material depicted is tantalum (Ta). As can be seen at bar 712, an interface of Ta and Fe has a fairly small positive Kᵢ, while an interface with Ta and Co has a much greater positive Kᵢ, as depicted by bar 714. As a result, a buffer layer of either Fe or Co may be utilized to interface with Ta; however, Co clearly has a bigger impact on overall Kᵢ when interfacing with Ta than Fe does.

The next material depicted is copper (Cu). As can be seen at bar 716, an interface of Cu and Fe has a positive Kᵢ, while an interface of Cu and Co has a much smaller positive Kᵢ, as depicted by bar 718. As a result, a buffer layer of either Fe or Co may be utilized to interface with Cu; however, Fe clearly has a bigger impact on overall Kᵢ when interfacing with Cu than Co does.

The next material depicted is magnesium oxide (MgO). As can be seen at bar 720 and bar 722, MgO has a positive Kᵢ when interfacing with either of Fe or Co. As a result, a buffer layer of either Fe or Co may be utilized to interface with MgO; however, an interface of MgO and Fe clearly generates a greater Kᵢ, as depicted by 720.

Moving farther to the right, the next material depicted is hafnium oxide (HfO₂). As can be seen at bar 724 and bar 726, HfO₂ has a positive Kᵢ when interfacing with either of Fe or Co. As a result, a buffer layer of either Fe or Co may be utilized to interface with HfO₂; however, an interface of HfO₂ and Co clearly generates a greater Kᵢ, as depicted by 726.

Both of the final materials, bars 728-734, involve ruthenium (Ru). As can be seen at bar 728 and bar 730, Ru has a positive Kᵢ when interfacing with a thin (e.g., 0.4-0.5 nm) layer of either of Fe or Co. As a result, a thin buffer layer of either Fe or Co may be utilized to interface with Ru; however, an interface of Ru and a thin layer of Fe clearly generates a greater Kᵢ, as depicted by 728. This is in contrast to the results depicted when utilizing a Ru layer in contact with a thick (e.g., >4 nm) layer of Fe or Co. As depicted by bars 732 and 734, a Ru layer when interfacing with either of thick Fe or Co has a negative Kᵢ. As a result, a thick buffer layer of either Fe or Co may not be desirable to interface with a Ru layer where the goal is to increase overall Kᵢ.

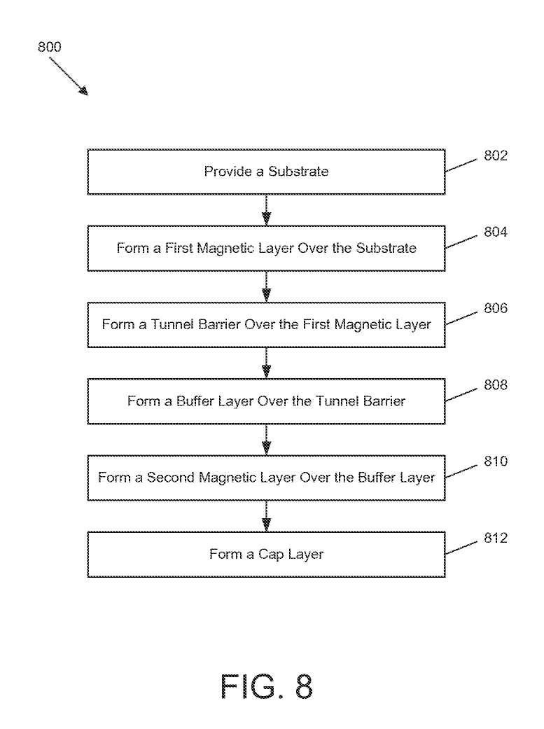

FIG. 8 illustrates a flow diagram for a process 800 of fabricating a magnetic tunnel junction (MTJ) in accordance with various embodiments of the present disclosure. The process may begin at 802, where a substrate may be provided. At block 804, a first magnetic layer may be formed over the substrate. At block 806, a tunnel barrier may be formed over the first magnetic layer. At block 808 a buffer layer, such as the buffer layers discussed herein, may be formed over the tunnel barrier. At block 810, a second magnetic layer may be formed over the buffer layer. Finally, at 812, a cap layer may be formed.

Each of these layers may be composed of any of the materials discussed herein or any other suitable material. In addition, the layers may be formed in any manner known in the art, such as, for example, sputter and/or vapor deposition. In some embodiments, the first magnetic layer may be a fixed magnetic layer while the second magnetic layer may be a free magnetic layer. In some embodiments, an additional buffer layer may be formed over the second magnetic layer prior to forming the cap layer at block 812. This additional buffer layer may be formed in place of, or in addition to, the buffer layer formed at block 808.

In some embodiments, additional sub-layers may be formed as part of the individual procedures. For example, to form the cap layer at block 812, an oxide sub-layer may be formed over the second magnetic layer, and a contact sub-layer may be formed over the oxide sub-layer. In some embodiments, in forming the first or second magnetic layers, a number of magnetic sub-layers may be formed that may be magnetically coupled. In these embodiments, buffer sub-layers may also be formed between the magnetic sub-layers.

FIG. 9 schematically illustrates an example computing device 900 that may include a magnetic tunnel junction (MTJ) (e.g., MTJ 128 of FIG. 1, 200 of FIG. 2, 300 of

FIG. 3, 400 of FIG. 4, 500 of FIGS. 5, and 600 of FIG. 6) as described herein, in accordance with some embodiments. The motherboard 902 may include a number of components, including but not limited to a processor 904 and at least one communication chip 906. The processor 904 may be physically and electrically coupled to the motherboard 902. In some implementations, the at least one communication chip 906 may also be physically and electrically coupled to the motherboard 902. In further implementations, the communication chip 906 may be part of the processor 904.

Depending on its applications, computing device 900 may include other components that may or may not be physically and electrically coupled to the motherboard 902. These other components may include, but are not limited to, volatile memory (e.g., dynamic random access memory (DRAM) 908), non-volatile memory (e.g., read-only memory (ROM) 910), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments, they might not. The communication chip 906 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 906 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 906 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 906 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 906 may operate in accordance with other wireless protocols in other embodiments.

The computing device 900 may include a plurality of communication chips 906. For instance, a first communication chip 906 may be dedicated to shorter range wireless communications such as Wi-Fi and Bluetooth, and a second communication chip 906 may be dedicated to longer range wireless communications such as GPS, EDGE, GPRS, CDMA, WiMAX, LTE, EV-DO, and others.

The processor 904 of the computing device 900 may include a die (e.g., die 102 of FIG. 1) having an MTJ (e.g., MTJ 128 of FIG. 1, 200 of FIG. 2, 300 of FIG. 3, 400 of FIG. 4, 500 of FIGS. 5, and 600 of FIG. 6) as described herein. For example, the die 102 of FIG. 1 may be mounted in a package assembly that is mounted on the motherboard 902. The term “processor” may refer to any device or portion of a device that processes electronic data from registers and/or memory to transform that electronic data into other electronic data that may be stored in registers and/or memory.

The communication chip 906 may also include a die (e.g., die 102 of FIG. 1) having an MTJ (e.g., MTJ 128 of FIG. 1, 200 of FIG. 2, 300 of FIG. 3, 400 of FIG. 4, 500 of FIGS. 5, and 600 of FIG. 6) as described herein. In further implementations, another component (e.g., memory device or other integrated circuit device) housed within the computing device 900 may contain a die (e.g., die 102 of FIG. 1) having a transistor electrode structure (e.g., MTJ 128 of FIG. 1, 200 of FIG. 2, 300 of FIG. 3, 400 of FIG. 4, 500 of FIGS. 5, and 600 of FIG. 6) as described herein.

In various implementations, the computing device 900 may be a mobile computing device, a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

### EXAMPLES

According to various embodiments, the present disclosure describes a method. Example 1 is a magnetic tunnel junction comprising: a cap layer; a tunnel barrier; a magnetic layer disposed between the cap layer and the tunnel barrier; and a buffer layer disposed between the magnetic layer and a selected one of the cap layer or the tunnel barrier, wherein an interfacial anisotropy of the buffer layer and the selected one of the cap layer or the tunnel barrier is greater than an interfacial anisotropy of the magnetic layer and the selected one of the cap layer or the tunnel barrier.

Example 2 may include the subject matter of Example 1, wherein the cap layer further comprises a contact sub-layer and an oxide sub-layer disposed between the contact sub-layer and the magnetic layer, wherein an interfacial anisotropy of the oxide sub-layer and the magnetic layer is greater than an interfacial anisotropy of the magnetic layer and the contact sub-layer.

Example 3 may include the subject matter of Example 2, wherein the oxide sub-layer comprises a conductive oxide.

Example 4 may include the subject matter of Example 1, wherein the buffer layer is a first buffer layer disposed between the magnetic layer and the cap layer, the magnetic tunnel junction further comprising: a second buffer layer disposed between the magnetic layer and the tunnel barrier, wherein an interfacial anisotropy of the second buffer layer and the tunnel barrier is greater than an interfacial anisotropy of the magnetic layer and the tunnel barrier.

Example 5 may include the subject matter of Example 1, wherein the magnetic layer is composed of a plurality of magnetic sub-layers that are magnetically coupled to form a single magnet.

Example 6 may include the subject matter of Example 5, wherein the plurality of magnetic sub-layers comprise one or more buffer sub-layers designed to increase an interfacial anisotropy of the magnetic layer.

Example 7 may include the subject matter of Example 6, wherein the plurality of magnetic sub-layers comprise a middle sub-layer disposed between a first outside magnetic sub-layer and a second outside magnetic sub-layer, wherein the middle sub-layer comprises one or more of tantalum (Ta) or hafnium (Hf), and wherein the first and second outside magnetic sub-layers comprise cobalt (Co), iron (Fe), and boron (B).

Example 8 may include the subject matter of Example 7, further comprising a buffer sub-layer disposed between the middle sub-layer and a selected one of the first or second outside magnetic sub-layers, wherein the buffer sub-layer comprises Co or Fe.

Example 9 may include the subject matter of Example 7, further comprising a first buffer sub-layer disposed between the middle sub-layer and the first outside magnetic sub-layer and a second buffer sub-layer disposed between the middle sub-layer and the second outside magnetic sub-layer, wherein the first and second buffer sub-layers comprise Co or Fe.

Example 10 may include the subject matter of Example 1, wherein the cap layer comprises tantalum (Ta) or hafnium (Hf).

Example 11 may include the subject matter of Example 1, wherein the tunnel barrier comprises magnesium oxide (MgO) or hafnium oxide (HfO₂).

Example 12 may include the subject matter of Example 1, wherein the magnetic layer comprises cobalt (Co), iron (Fe), and boron (B).

Example 13 may include the subject matter of Example 1, wherein the buffer layer comprises iron (Fe) or cobalt (Co).

Example 14 may include the subject matter of Example 1, wherein the buffer layer comprises cobalt (Co) rich cobalt (Co), iron (Fe), and boron (B), CoFeB, and wherein the magnetic layer comprises Fe rich CoFeB.

Example 15 may include the subject matter of any one of Examples 1-14, wherein the magnetic layer is a free magnetic layer.

Example 16 is a method of forming a magnetic tunnel junction comprising: providing a substrate; forming a first magnetic layer over the substrate; forming a tunnel barrier over the first magnetic layer; forming a second magnetic layer over the tunnel barrier; forming a cap layer over the second magnetic layer; and forming a buffer layer, the buffer layer being disposed between the second magnetic layer and a selected one of the cap layer or the tunnel barrier, wherein an interfacial anisotropy of the buffer layer and the selected one of the cap layer or the tunnel barrier is greater than an interfacial anisotropy of the second magnetic layer and the selected one of the cap layer or the tunnel barrier.

Example 17 may include the subject matter of Example 16, wherein forming the cap layer further comprises: forming an oxide sub-layer over the second magnetic layer; and forming a contact sub-layer over the oxide sub-layer.

Example 18 may include the subject matter of Example 17, wherein the oxide sub-layer comprises a conductive oxide.

Example 19 may include the subject matter of Example 16, wherein the buffer layer is a first buffer layer disposed between the second magnetic layer and the cap layer, the method further comprising: forming a second buffer layer, wherein the second buffer layer is disposed between the second magnetic layer and the tunnel barrier, wherein an interfacial anisotropy of the second buffer layer and the tunnel barrier is greater than an interfacial anisotropy of the second magnetic layer and the tunnel barrier.

Example 20 may include the subject matter of Example 16, wherein forming the second magnetic layer further comprises forming a plurality of magnetic sub-layers that are magnetically coupled.

Example 21 may include the subject matter of Example 20, wherein forming the second magnetic layer further comprises forming a buffer sub-layer disposed between two magnetic sub-layers of the plurality of magnetic sub-layers, wherein the buffer sub-layer is designed to increase an interfacial anisotropy of the second magnetic layer.

Example 22 may include the subject matter of Example 20, wherein the plurality of magnetic sub-layers comprise a middle sub-layer formed between a first outside magnetic sub-layer and a second outside magnetic sub-layer, wherein the middle sub-layer comprises one or more of tantalum (Ta) or hafnium (Hf), and wherein the first and second outside magnetic sub-layers comprise cobalt (Co), iron (Fe), and boron (B).

Example 23 may include the subject matter of Example 22, further comprising forming a buffer sub-layer disposed between the middle sub-layer and a selected one of the first or second outside magnetic sub-layers, wherein the buffer sub-layer comprises Co or Fe.

Example 24 may include the subject matter of Example 22, further comprising forming a first buffer sub-layer between the middle sub-layer and the first outside magnetic sub-layer and forming a second buffer sub-layer between the middle sub-layer and the second outside magnetic sub-layer, wherein the first and second buffer sub-layers comprise Co or Fe.

Example 25 may include the subject matter of Example 16, wherein the cap layer comprises tantalum (Ta) or hafnium (Hf).

Example 26 may include the subject matter of Example 16, wherein the tunnel barrier comprises magnesium oxide (MgO) or hafnium oxide (HfO₂).

Example 27 may include the subject matter of Example 16, wherein the first magnetic layer and the second magnetic layer comprise cobalt (Co), iron (Fe), and boron (B).

Example 28 may include the subject matter of Example 16, wherein the buffer layer comprises iron (Fe) or cobalt (Co).

Example 29 may include the subject matter of Example 15, wherein the buffer layer comprises cobalt (Co) rich cobalt (Co), iron (Fe), and boron (B), CoFeB, and wherein the magnetic layer comprises Fe rich CoFeB.

Example 30 may include the subject matter of Example 15-27, wherein the second magnetic layer is a free magnetic layer and the first magnetic layer is a fixed magnetic layer.

Example 31 is a spin transfer torque memory (STTM) comprising: a bit line; a sense line; a magnetic tunnel junction coupling the bit line with the sense line, wherein the magnetic tunnel junction comprises: a cap layer, a tunnel barrier, and a magnetic layer disposed between the cap layer and the tunnel barrier; and a buffer layer disposed between the magnetic layer and a selected one of the cap layer or the tunnel barrier, wherein an interfacial anisotropy of the buffer layer and the selected one of the cap layer or the tunnel barrier is greater than an interfacial anisotropy of the magnetic layer and the selected one of the cap layer or the tunnel barrier.

Example 32 may include the subject matter of Example 31, wherein the cap layer further comprises a contact sub-layer and an oxide sub-layer disposed between the contact sub-layer and the magnetic layer, wherein an interfacial anisotropy of the oxide sub-layer and the magnetic layer is greater than an interfacial anisotropy of the magnetic layer and the contact sub-layer.

Example 33 may include the subject matter of Example 32, wherein the oxide sub-layer comprises a conductive oxide.

Example 34 may include the subject matter of Example 31, wherein the buffer layer is a first buffer layer disposed between the magnetic layer and the cap layer, the magnetic tunnel junction further comprising: a second buffer layer disposed between the magnetic layer and the tunnel barrier, wherein an interfacial anisotropy of the second buffer layer and the tunnel barrier is greater than an interfacial anisotropy of the magnetic layer and the tunnel barrier.

Example 35 may include the subject matter of Example 31, wherein the magnetic layer is composed of a plurality of magnetic sub-layers that are magnetically coupled to form a single magnet.

Example 36 may include the subject matter of Example 35, wherein the plurality of magnetic sub-layers comprise one or more buffer sub-layers designed to increase an interfacial anisotropy of the magnetic layer.

Example 37 may include the subject matter of Example 36, wherein the plurality of magnetic sub-layers comprise a middle sub-layer disposed between a first outside magnetic sub-layer and a second outside magnetic sub-layer, wherein the middle sub-layer comprises one or more of tantalum (Ta) or hafnium (Hf), and wherein the first and second outside magnetic sub-layers comprise cobalt (Co), iron (Fe), and boron (B).

Example 38 may include the subject matter of Example 37, further comprising a buffer sub-layer disposed between the middle sub-layer and a selected one of the first or second outside magnetic sub-layers, wherein the buffer sub-layer comprises Co or Fe.

Example 39 may include the subject matter of Example 37, further comprising a first buffer sub-layer disposed between the middle sub-layer and the first outside magnetic sub-layer and a second buffer sub-layer disposed between the middle sub-layer and the second outside magnetic sub-layer, wherein the first and second buffer sub-layers comprise Co or Fe.

Example 40 may include the subject matter of Example 31, wherein the cap layer comprises tantalum (Ta) or hafnium (Hf).

Example 41 may include the subject matter of Example 31, wherein the tunnel barrier comprises magnesium oxide (MgO) or hafnium oxide (HfO₂).

Example 42 may include the subject matter of Example 31, wherein the magnetic layer comprises cobalt (Co), iron (Fe), and boron (B).

Example 43 may include the subject matter of Example 31, wherein the buffer layer comprises iron (Fe) or cobalt (Co).

Example 44 may include the subject matter of Example 29, wherein the buffer layer comprises cobalt (Co) rich cobalt (Co), iron (Fe), and boron (B), CoFeB, and wherein the magnetic layer comprises Fe rich CoFeB.

Example 45 may include the subject matter of Example 31-43, wherein the magnetic layer is a free magnetic layer.

Example 46 may include the subject matter of Example 45, wherein the STTM is a perpendicular STTM wherein the magnetic layer has an out of plane polarization (pSTTM).

Example 47 may include the subject matter of Example 46, wherein the STTM is part of a random access memory (RAM) module.

1-24. (canceled)

25. A magnetic tunnel junction comprising:
a cap layer;
a tunnel barrier;
a magnetic layer disposed between the cap layer and the tunnel barrier; and
a buffer layer disposed between the magnetic layer and a selected one of the cap layer or the tunnel barrier, wherein an interfacial anisotropy of the buffer layer and the selected one of the cap layer or the tunnel barrier is greater than an interfacial anisotropy of the magnetic layer and the selected one of the cap layer or the tunnel barrier.

26. The magnetic tunnel junction of claim 25, wherein the cap layer further comprises a contact sub-layer and an oxide sub-layer disposed between the contact sub-layer and the magnetic layer, wherein an interfacial anisotropy of the oxide sub-layer and the magnetic layer is greater than an interfacial anisotropy of the magnetic layer and the contact sub-layer.

27. The magnetic tunnel junction of claim 26, wherein the oxide sub-layer comprises a conductive oxide.

28. The magnetic tunnel junction of claim 25, wherein the buffer layer is a first buffer layer disposed between the magnetic layer and the cap layer, the magnetic tunnel junction further comprising:
a second buffer layer disposed between the magnetic layer and the tunnel barrier, wherein an interfacial anisotropy of the second buffer layer and the tunnel barrier is greater than an interfacial anisotropy of the magnetic layer and the tunnel barrier.

29. The magnetic tunnel junction of claim 25, wherein the magnetic layer is composed of a plurality of magnetic sub-layers that are magnetically coupled to form a single magnet.

30. The magnetic tunnel junction of claim 29, wherein the plurality of magnetic sub-layers comprise one or more buffer sub-layers designed to increase an interfacial anisotropy of the magnetic layer.

31. The magnetic tunnel junction of claim 30, wherein the plurality of magnetic sub-layers comprise a middle sub-layer disposed between a first outside magnetic sub-layer and a second outside magnetic sub-layer, wherein the middle sub-layer comprises one or more of tantalum (Ta) or hafnium (Hf), and wherein the first and second outside magnetic sub-layers comprise cobalt (Co), iron (Fe), and boron (B).

32. The magnetic tunnel junction of claim 31, further comprising a buffer sub-layer disposed between the middle sub-layer and a selected one of the first or second outside magnetic sub-layers, wherein the buffer sub-layer comprises Co or Fe.

33. The magnetic tunnel junction of claim 31, further comprising a first buffer sub-layer disposed between the middle sub-layer and the first outside magnetic sub-layer and a second buffer sub-layer disposed between the middle sub-layer and the second outside magnetic sub-layer, wherein the first and second buffer sub-layers comprise Co or Fe.

34. The magnetic tunnel junction of claim 25, wherein the cap layer comprises tantalum (Ta) or hafnium (Hf).

35. The magnetic tunnel junction of claim 25, wherein the tunnel barrier comprises magnesium oxide (MgO) or hafnium oxide (HfO₂).

36. The magnetic tunnel junction of claim 25, wherein the magnetic layer comprises cobalt (Co), iron (Fe), and boron (B).

37. The magnetic tunnel junction of claim 25, wherein the buffer layer comprises iron (Fe) or cobalt (Co).

38. The magnetic tunnel junction of claim 25, wherein the buffer layer comprises cobalt (Co) rich cobalt (Co), iron (Fe), and boron (B), CoFeB, and wherein the magnetic layer comprises Fe rich CoFeB.

39. The magnetic tunnel junction of claim 25, wherein the magnetic layer is a free magnetic layer.

40. A spin transfer torque memory (STTM) comprising:
a bit line;
a sense line;
a magnetic tunnel junction coupling the bit line with the sense line, wherein the magnetic tunnel junction comprises:
a cap layer, a tunnel barrier, and a magnetic layer disposed between the cap layer and the tunnel barrier; and
a buffer layer disposed between the magnetic layer and a selected one of the cap layer or the tunnel barrier, wherein an interfacial anisotropy of the buffer layer and the selected one of the cap layer or the tunnel barrier is greater than an interfacial anisotropy of the magnetic layer and the selected one of the cap layer or the tunnel barrier.

41. The STTM of claim 40, wherein the buffer layer is a first buffer layer disposed between the magnetic layer and the cap layer, the magnetic tunnel junction further comprising:
a second buffer layer disposed between the magnetic layer and the tunnel barrier, wherein an interfacial anisotropy of the second buffer layer and the tunnel barrier is greater than an interfacial anisotropy of the magnetic layer and the tunnel barrier.

42. The STTM of claim 40, wherein the STTM is a perpendicular STTM wherein the magnetic layer is a free magnetic layer with an out of plane polarization, and wherein the STTM is part of a random access memory (RAM) module.

43. A method of forming a magnetic tunnel junction comprising:
providing a substrate;
forming a first magnetic layer over the substrate;
forming a tunnel barrier over the first magnetic layer;
forming a second magnetic layer over the tunnel barrier;
forming a cap layer over the second magnetic layer; and
forming a buffer layer, the buffer layer being disposed between the second magnetic layer and a selected one of the cap layer or the tunnel barrier, wherein an interfacial anisotropy of the buffer layer and the selected one of the cap layer or the tunnel barrier is greater than an interfacial anisotropy of the second magnetic layer and the selected one of the cap layer or the tunnel barrier.

44. The method of claim 43, wherein forming the cap layer further comprises:
forming an oxide sub-layer over the second magnetic layer; and
forming a contact sub-layer over the oxide sub-layer, and wherein the oxide sub-layer comprises an oxide.

45. The method of claim 43, wherein the buffer layer is a first buffer layer disposed between the second magnetic layer and the cap layer, the method further comprising:
forming a second buffer layer, wherein the second buffer layer is disposed between the second magnetic layer and the tunnel barrier, wherein an interfacial anisotropy of the second buffer layer and the tunnel barrier is greater than an interfacial anisotropy of the second magnetic layer and the tunnel barrier.

46. The method of claim 43, wherein forming the second magnetic layer further comprises:
forming a plurality of magnetic sub-layers that are magnetically coupled; and
forming a buffer sub-layer disposed between two magnetic sub-layers of the plurality of magnetic sub-layers, wherein the buffer sub-layer is designed to increase an interfacial anisotropy of the second magnetic layer.

47. The method of claim 46, wherein the plurality of magnetic sub-layers comprise a middle sub-layer formed between a first outside magnetic sub-layer and a second outside magnetic sub-layer, the method further comprising forming a buffer sub-layer disposed between the middle sub-layer and a selected one of the first or second outside magnetic sub-layers, wherein the middle sub-layer comprises one or more of tantalum (Ta) or hafnium (Hf), and wherein the first and second outside magnetic sub-layers comprise cobalt (Co), iron (Fe), and boron (B), and wherein the buffer sub-layer comprises Co or Fe.

48. The method of claim 47, further comprising forming a first buffer sub-layer between the middle sub-layer and the first outside magnetic sub-layer and forming a second buffer sub-layer between the middle sub-layer and the second outside magnetic sub-layer, wherein the first and second buffer sub-layers comprise Co or Fe.

49. The method of claim 43, wherein the cap layer comprises tantalum (Ta) or hafnium (Hf); the tunnel barrier comprises magnesium oxide (MgO) or hafnium oxide (HfO₂); the first magnetic layer and the second magnetic layer comprise cobalt (Co), iron (Fe), and boron (B); or the buffer layer comprises iron (Fe) or cobalt (Co).
